(19) United States
(12) Patent Application Publication
(10) Pub. No.: US 2024/0407319 A1
(43) Pub. Date: Dec. 12, 2024

(54) HYBRID SYSTEM FOR CONTROLLED ENVIRONMENT MANAGEMENT IN AGRICULTURAL APPLICATIONS

(71) Applicant: SHINOBI HOLDINGS LTD., Bnei-Brak (IL)

(72) Inventors: Asaff Moshe BAGG, Maabarot (IL); Avraham SHAHAR, Kfar Yedidia (IL)

(21) Appl. No.: 18/811,315

(22) Filed: Aug. 21, 2024

Related U.S. Application Data
(63) Continuation-in-part of application No. PCT/IL2023/050182, filed on Feb. 21, 2023.

(30) Foreign Application Priority Data
Feb. 22, 2022 (IL) 290813

(51) Int. Cl. A01K 1/00; A01G 9/24; A01K 31/20; H05K 7/20

(52) U.S. Cl. CPC A01K 1/0047; A01G 9/246; A01K 31/20; H05K 7/20836

(57) ABSTRACT

The invention relates to a self-sustainable environment regulation system that utilizes heat energy dissipated from energy-intensive facilities, such as data centers, AI systems, and crypto-mining operations. This system is designed for use in controlled environments, including greenhouses and livestock housing, such as poultry coops for broiler and egg production. By harnessing excess heat from these facilities, the system provides effective temperature regulation for agricultural applications, promoting optimal conditions for plant growth and livestock welfare. The system comprises a closed-loop setup that integrates the heat energy with autonomous temperature control mechanisms, ensuring efficient and sustainable management of the environment.

### CROSS-REFERENCE TO RELATED APPLICATIONS

This application is a continuation-in-part of International Application No. PCT/IL2023/050182, filed on Feb. 21, 2023, which, in turn, claims priority to Israeli Patent Application No. 290813, filed on Feb. 22, 2022, both of which are hereby incorporated herein by reference in their entirety/entireties for all purposes.

### FIELD OF THE INVENTION

The invention relates to a self-sustainable system that harnesses energy generated from energy-intensive facilities (such as data centers, AI systems, crypto-mining of digital coins, etc.) for use in controlled environments, particularly for agricultural applications such as greenhouses and livestock housing, including poultry coops for broiler and egg production. The system utilizes renewable energy sources and autonomous control mechanisms to maintain optimal temperature and environmental conditions, promoting improved growth, health, and productivity in both plant and animal operations.

### BACKGROUND OF THE INVENTION

Energy-intensive facilities, such data centers, Artificial Intelligence (AI) systems, and crypto-currency mining has become a global phenomenon in recent years. For example, crypto-currency mining is the process that adds new digital coin transactions to the distributed ledger known as the “blockchain.” Mining is also how new digital coins come into existence as a reward for being the first miner to add the next block of transactions to the blockchain. Generating digital coins requires a lot of computational energy and processing time. As such, this requires large amounts of electricity. The actual running of computers, servers and related hardware in a digital mining center generates a considerable amount energy in the form of heat. This heat is considered a wasted byproduct of digital mining and is usually left to escape into the atmosphere. Generating such large amounts of heat from digital mining also serves to reduce mining performance and efficiency since computers and servers tend to function most effectively at some optimum temperature. To circumvent the issue of high cost due to large electricity consumption, many companies have sought to strategically install digital-coin mining centers where energy prices are lowest.

However, since the demand for data centers, AI systems, and crypto-currency is growing exponentially this solution is not sustainable. Fossil fuel still accounts for the vast majority of electricity production worldwide. For example, with the increasing demand for crypto-currency, this will only add to fossil fuel consumption which poses a serious problem regarding the global effort to mitigate anthropogenic climate change.

Merely seeking energy-intensive facilities locations that have cheap electricity tariffs is not a sustainable solution to the problem. Electricity prices change all the time and the locations with the cheapest energy prices often tend to be those that rely most heavily on fossil fuels, exacerbating the problem of anthropogenic climate change.

In the agricultural sector, maintaining controlled environments is crucial for optimizing growth and productivity. For greenhouses, precise control of temperature, humidity, and ventilation is necessary to achieve maximum crop yields and quality. Similarly, in the livestock industry, particularly in poultry housing, maintaining a stable and suitable temperature is essential for the health, growth, and welfare of the animals.

Traditional systems for climate control in these environments often rely on non-renewable energy sources and manual operation, which can be inefficient, costly, and environmentally unsustainable. Moreover, the lack of precise control can lead to suboptimal conditions, resulting in reduced yields, poor animal welfare, and increased mortality rates.

Therefore there is a need for an efficient, sustainable, and automated system that can adapt to the specific needs of both plants and animals.

It is an object of the present invention to provide a hybrid system that offers a a sustainable solution to energy-intensive environments, such as greenhouses and livestock housing, by utilizing heat generated from facilities such as data centers, AI systems, and crypto-mining operations. The system creates a closed-loop environment that harnesses this heat to effectively control and maintain the climate within greenhouses and poultry coops.

Other advantages and objects of the invention will become apparent as the description proceeds.

### SUMMARY OF THE INVENTION

In one aspect, the present invention relates to an environment regulation system comprising:
a controlled environment area, including at least one of a greenhouse or a livestock housing unit;
a first temperature regulation system for said controlled environment area;
an energy-intensive system comprising a plurality of computers and/or servers, wherein heat energy dissipated from the energy-intensive system is used to regulate the temperature in the controlled environment area, wherein the energy-intensive system further comprises a second temperature regulation system configured to maintain the operational temperature of the computers and/or servers within an optimal temperature range;
a power source configured to activate the first temperature regulation system in the controlled environment area and the second temperature regulation system for the energy-intensive system; and
a control system configured to adjust the operation of the first temperature regulation system based on environmental parameters including but not limited to growth stages, seasonal variations, and other relevant factors.

In one aspect, the controlled environment area is adapted for agricultural applications, including greenhouses for growing plants and poultry coops for broiler and egg production.

In one aspect, the control system includes sensors and automated controls that dynamically adjust the temperature regulation based on real-time data of environmental conditions and growth stages of the plants or livestock.

In one aspect, the control system includes a predictive algorithm that considers seasonal changes and other environmental parameters to optimize temperature regulation throughout the year.

In one aspect, the physical structure of the controlled environment area includes design features to enhance thermal insulation and energy efficiency.

In one aspect, the design features to enhance thermal insulation and energy efficiency are selected from the group consisting of: thermal screens, cooling system, ventilation, irrigation system, duct system, carbon capture device, or any combination thereof.

In one aspect, the power source comprises a renewable energy source, a grid power source, or a combination thereof.

In another aspect, the present invention relates to a method of regulating the environment in a controlled area comprising:
dissipating heat energy from an energy-intensive system to the controlled environment area;
adjusting the temperature in the controlled environment area using a first temperature regulation system based on real-time data and predictive algorithms that account for growth stages, seasonal variations, and other environmental parameters;
maintaining optimal operational temperature of the energy-intensive system using a second temperature regulation system; and
utilizing a control system to coordinate the operation of the temperature regulation systems and the power source to ensure efficient energy use.

In another aspect, the present invention relates to a sustainable system of energy-intensive facilities (e.g., AI systems, crypto-currency mining, data center, etc.) where the heat generated by system (e.g., due to the digital-mining) is used to warm greenhouses to grow crops sustainably. The present invention is a closed-system wherein all the energy required for digital mining of coins or for operating a data center (e.g., for performing critical functions that are important for running the daily operations of top scientific, economic, and technological organizations worldwide) and the production of crops is from renewable energy sources. One goal of the present invention is to provide a carbon neutral solution to digital mining in conjunction with sustainable crop production.

In one embodiment the invention is directed towards a system which regulates the environment inside a greenhouse or network of greenhouses. A temperature regulation system is incorporated within the greenhouses to ensure that it maintains an optimal temperature for crop production. Furthermore, heat generated from a data center, AI system, or crypto-mining system is directed towards the greenhouse to warm the atmosphere within it or to directly warm the soil where plants grow. In a further embodiment, the data center or the crypto-mining system itself has a temperature regulation system to ensure that it runs and functions at an optimal temperature.

In a further embodiment, a power source, preferably a renewable energy source such as solar or wind, is further used to control the temperature regulation systems of the greenhouses and the energy-intensive facility such as the AI system, crypto-mining system or data center.

In a further embodiment, the data center or digital mining system utilizes an energy storage facility to store energy for later use in the running of the various systems of the invention.

In another embodiment a carbon capture device is incorporated to capture carbon dioxide (CO₂) from the atmosphere, redirecting it towards the interior of the greenhouse, to increase the fertilization effect on crops; CO₂ being a key component in photosynthesis and hence plant growth. In a further embodiment the carbon captured is liquefied at very low temperatures and used to cool the energy-intensive facility to maintain its temperature at an optimal value. Typically such a system will be placed underground.

In a further embodiment, the plant growing system as a whole can be soil-based, but is not limited to this. Indeed, the plants within the greenhouse can be grown without soil, such as hydroponics, in water. Furthermore, the plants themselves can be grown individually or collectively. In another embodiment, the plants can be grown in vertical farms. A vertical farm being one in which plants are grown in vertically stacked layers. Furthermore, crops can be grown by trellising or any frame and/or structure that can support the growth of plants.

In yet another aspect, the present invention is an environment regulation system, comprising:
A greenhouse;
A first temperature regulation system for the said greenhouse;
A energy-intensive system comprising a plurality of computers and servers wherein the heat energy generated from the energy-intensive system is used to warm the said greenhouse;
The said energy-intensive system further comprising a second temperature regulation system configured to maintain the operational temperature of the said plurality of computers and servers within an optimal temperature range; and
A power source which is configured to activate the first temperature regulation system in the said greenhouse and as well as the second temperature regulation system for the energy-intensive system.

In one aspect, the power source is a plurality of solar panels. In some embodiments, the plurality of solar panels moves to be optimally directed towards the sun.

In one aspect, the greenhouse further comprises an air outlet and/or inlet configured to transfer air out of or into the greenhouse.

In another aspect, the system further comprises a plurality of humidity sensors and humidity control unit.

In yet another aspect, the temperature of the said greenhouse can be programmed to simulate a day-night and seasonal environment.

In another aspect, the system further comprises an energy storage unit wherein surplus energy generated from the said plurality of solar cells is stored in the said storage unit. In some embodiments, the storage unit is configured to supply energy to the temperature regulation system in the greenhouse and/or to the temperature regulation system in the energy-intensive system.

In another aspect, the system further comprises an external carbon capture device whose energy is supplied by the said plurality of solar panels. In some embodiments, carbon dioxide (CO₂) captured by the said external carbon capture device is directed towards the interior atmosphere of the said greenhouse, to fertilize plants growing inside the greenhouse.

In yet another aspect, the system further comprises a CO₂ liquefaction system wherein the energy generated from the said plurality of solar panels is directed towards the CO₂ liquefaction system wherein the said external carbon capture device provides CO₂ to the said CO₂ liquefaction system.

According to some embodiments, liquid CO₂ from the said CO₂ liquefaction system is used to cool the said energy-intensive system to maintain an optimal temperature.

In still another aspect, the greenhouse and the energy-intensive system can be modular and built to scale.

### BRIEF DESCRIPTION OF THE DRAWINGS

In the drawings:

FIG. 1 schematically illustrates a block diagram of an environment regulation system, according to an embodiment of the invention;

FIG. 2 is a schematic representation of the system in a ‘winter mode’, according to an embodiment of the invention;

FIG. 3 is a schematic representation of the system installed above the ground level, according to an embodiment of the invention;

FIG. 4A schematically illustrates a transparent top view of the environment regulation system, according to an embodiment of the invention;

FIG. 4B a detailed view of ducts arrangement in conjunction with the heating and cooling room of the system of FIG. 4A, according to an embodiment of the invention;

FIG. 5 schematically illustrates the greenhouse provided with a pad climate system, according to an embodiment of the invention; and

FIG. 6 schematically illustrates a livestock environment regulation system, according to an embodiment of the invention.

### DETAILED DESCRIPTION OF THE INVENTION

This system is designed as a hybrid solution for managing the climate within controlled environments such as greenhouses and poultry houses, including those for broilers and egg production. The system harnesses heat generated from facilities such as data centers, AI systems, and crypto-mining operations to regulate heating and cooling, ensuring optimal conditions for both plant and animal growth, as well as their productions.

Reference will now be made to several embodiments of the present invention, examples of which are illustrated in the accompanying figures. Wherever practicable, similar or identical reference numbers may be used in the figures and may indicate similar or identical functionality. The figures depict embodiments of the present invention for purposes of illustration only. One skilled in the art will readily recognize from the following description that alternative embodiments of the structures illustrated herein may be employed without departing from the principles of the invention described herein.

As stated above, one of the goals of the present invention is to provide a sustainable system (e.g., of crop production) by utilizing the ‘wasted’ heat energy from an energy-intensive facility such as a data center or digital crypto-currency mining. Although the following examples and description refer to an energy-intensive facility in the form of a digital crypto-currency mining system, it should be emphasized that the present invention may refer to any other form of energy-intensive facilities that may operate round the clock. Such energy-intensive facilities usually comprise machines that run constantly and are surrounded by a plurality of other machines doing the same thing.

In one embodiment, the hybrid system is tailored for greenhouse environments. It actively monitors and adjusts temperature, humidity, and ventilation to create an ideal atmosphere for various crops. By utilizing heat generated from facilities such as data centers, AI systems, and crypto-mining operations, the system minimizes energy consumption while maximizing crop yield and quality. The autonomous control mechanisms ensure that the internal environment is consistently maintained according to the specific needs of the plants throughout their growth cycle.

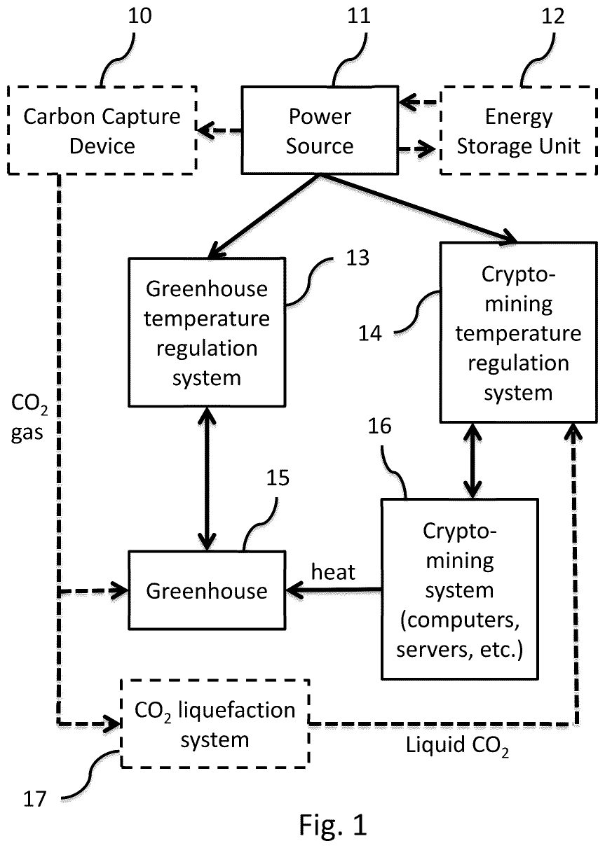

FIG. 1 shows a schematic of how the greenhouse-crypto-mining environment functions. In FIG. 1, solid black squares represent individual components of the system as related to the basic function of the invention, whereas dotted squares represent additional components and embodiments that will become clear below.

Briefly, a greenhouse 15, or network of greenhouses, is heated by a crypto-mining system 16. The crypto-mining system 16 can include any of the hardware and software necessary to carry out the purpose of crypto-mining. Therefore, a crypto-mining system 16 can include, but is not limited to, a plurality of personal computers (PCs), customized computers, servers, data centers, hard drives, cloud-based systems, and other components commonly found in a crypto-mining “rig” such as motherboards, hardware devices associated with RAM, central processing units (CPUs), graphics processing units (GPUs) and any data storage component. Generally, digital mining consumes large amounts of electrical energy, producing waste energy. It is this wasted heat energy that the present invention utilizes.

It should be noted that herein, all reference to heat and/or waste energy as generated by the crypto-mining system refers non-specifically to any type of crypto-mining, digital-coin mining and the like. Indeed, these terms may be used interchangeably without detracting from the general scope of the invention, namely, utilizing wasted heat energy from crypto-mining to warm greenhouses.

The greenhouse 15 is connected to a temperature regulation system 13. This temperature regulation system 13 is configured to maintain the greenhouse's temperature at an appropriate optimal temperature. Different crops require different ambient conditions and, in one embodiment, the temperature regulation system 13 can be configured to optimize a particular crop metric. Such metrics can include, but is not limited to, yield, crop quality, water content, crop size, and other features that are dependent on the ambient environment and conditions in the greenhouse. The greenhouse itself 15 is constantly being monitored by the temperature regulation system 13 to ensure that an optimal, or particular environment is maintained.

The temperature regulation system 13 includes autonomous controls that continuously monitor and adjust environmental conditions within the greenhouse 15. Using real-time data from various sensors, the system autonomously regulates heating, cooling, and humidity levels to maintain optimal conditions for plant growth. Suitable algorithms process data on temperature, humidity, and other environmental factors, enabling the system to automatically adjust settings to adapt to changing conditions. This reduces the need for manual intervention and ensures consistent and efficient management of the greenhouse environment.

As such, all of the basic components that are required to maintain a temperature regulation system are incorporated into the temperature regulation system of the greenhouse 13 such as sensors, heaters, radiators, coolers, vents, valves, fans, light sources, etc. In one embodiment, the temperature regulation system 13 can include the capability of programming an daily/weekly/monthly environment cycle, to ensure optimal conditions for the crops in the greenhouse 15. For example, the temperature regulation system 13 can be programmed to simulate day and night, or warm and cold periods of the day or week. In one embodiment, the temperature regulation system can also simulate seasonal changes, for example akin to a hibernation period. Indeed, there is no limit to what could be programmed to ensure that a desired outcome will be achieved. The temperature regulation system in the greenhouse 13 can include any method of temperature regulation such as air conditioning units, heaters, a heating system, chillers and fans.

In one embodiment for cooling the greenhouse the method of cooling is carried out by installing a system of wet cardboards through which the outside hot air flows. This system, combined with a system of fans, enables the inside temperature of the greenhouse to be reduced and increases the humidity. The said wet pad system includes cardboard wet pads, gutters, pipes for water disposition, pumps, a water tank and a pipe system for water supply. Based on the type of crop, the appropriate temperature and humidity are directed at specific locations with the greenhouse, controlling the environment therein. Typically, the placement of the cooling pads and the fans depends on the direction of sunlight and the wind.

The greenhouse itself 15 can be primarily made of glass, or other fully transparent or translucent materials such as Perspex, hard and soft plastics; it can also include polyethylene covers. The greenhouses can also include any standard irrigation system, be it irrigation from above (e.g., spraying) the plants and/or in or on the soil itself, such as drip irrigation.

In a further embodiment the greenhouses can use mobile thermal screens. These thermal screens are partly opaque sheets of material (such as plastic) that cover different parts of the crop nursery to control the amount of sunlight that is incident on the crops themselves. Typically, these thermal screens are placed on racks above the crop nurseries and move into position above a certain section of crops where the amount of light arriving on the crops needs to be reduced and/or restricted.

Regarding the growing of plants and/or any crops, these can include any type of vegetable, fruit, leaf, vine, root or other. The present application refers generally to plants and/or crops, but it will be understood that this includes any type of organic matter that is grown. Plants can be grown in soil, optionally with fertilizers, or hydroponically in water, in troughs, individually, and any combination thereof etc.

In one embodiment, integrated into the structure of the greenhouse itself 15 vents can be placed on the exterior walls and/or panels to allow air from the atmosphere to either flow in to or flow out of the greenhouse, as a way to control the temperature inside the greenhouse 15. For example, if it is a very hot or cold day outside the greenhouse, the temperature regulation system can be used to either cool, or heat the internal environment of the greenhouse 15. Furthermore, as part of the environmental system within the greenhouse 15, an important component is humidity control. In a further embodiment, and in order to optimally control the environment within the greenhouse, humidity sensors and regulators are installed to control and ensure optimal humidity. The motivation for this is that different crops require different ambient conditions, including temperature, humidity and atmospheric content. In one embodiment, rain from outside is collected in a rain collection device to be used by the humidity control system with water.

The temperature regulation system of the greenhouse 13 is connected to a power source 11. In keeping with the stated goal of the present invention, ideally the power source will be from a renewable energy source such as solar energy, wind, biomass, geothermal, tidal energy, etc. Primarily, the power source will be solar or wind energy, and these will be expanded upon below.

In one embodiment the power source 11 is solar energy from a plurality of solar panels. Furthermore, this plurality of solar panels can be installed away from the greenhouse, or on the greenhouse itself. In a further embodiment the plurality of solar panels can track the position of the sun and move, tilt or align themselves to optimally increase the efficiency of energy conversion from the sun i.e., the solar panels can be programmed to always point towards the sun, ostensibly increasing the chance of generating the most amount of energy.

In one embodiment, the power source is a plurality of wind turbines. Furthermore, the plurality wind turbines can be used in conjunction with a plurality solar panels, all providing electrical power to the system as a whole.

In a further embodiment, excess energy generated from any of the power sources 11 can be stored in an energy storage unit 12. The energy storage unit 12 can take on any form, such as a battery or other potential energy storage device. This energy storage unit 12 can be placed inside the greenhouse 15, outside it or off-site. Furthermore, excess energy can optionally be sold back to an energy provider, if the system is connected to a mains power supply. In one embodiment, for the purposes of energy security, the whole system can be optionally connected to a mains power supply in the event of a systems failure or a lack of energy generated from the renewable sources.

In the present invention the crypto-mining system can be modular and therefore easily scalable. In an embodiment of the invention, the crypto-mining hardware can be continuously added to, without detracting from the scope of the invention. Furthermore, a system of greenhouses 15 can also be modular, as a crypto-mining enterprise increases in size, creating a scalable greenhouse/crypto-mining network, as the sustainable system expands.

Turning back to the crypto-mining system 16, this is connected to a crypto-mining temperature regulation system 14. Crypto-mining systems generate a lot of heat and they are known to function most efficiently within a particular temperature range. This temperature range can be selected for and customized depending on the specific crypto-mining system that is installed. The crypto-mining temperature regulation system 14 therefore can include any type of air conditioning, water cooling system, heat exchangers or the like. The temperature regulation system 13 described above can use the same temperature regulation system 14. Thus, the temperature regulation system 13, 14 of the greenhouse and the crypto-mining system can be connected and operated together, ensuring that both the greenhouse 15 and the crypto-mining system 16 are cooled/heated as required.

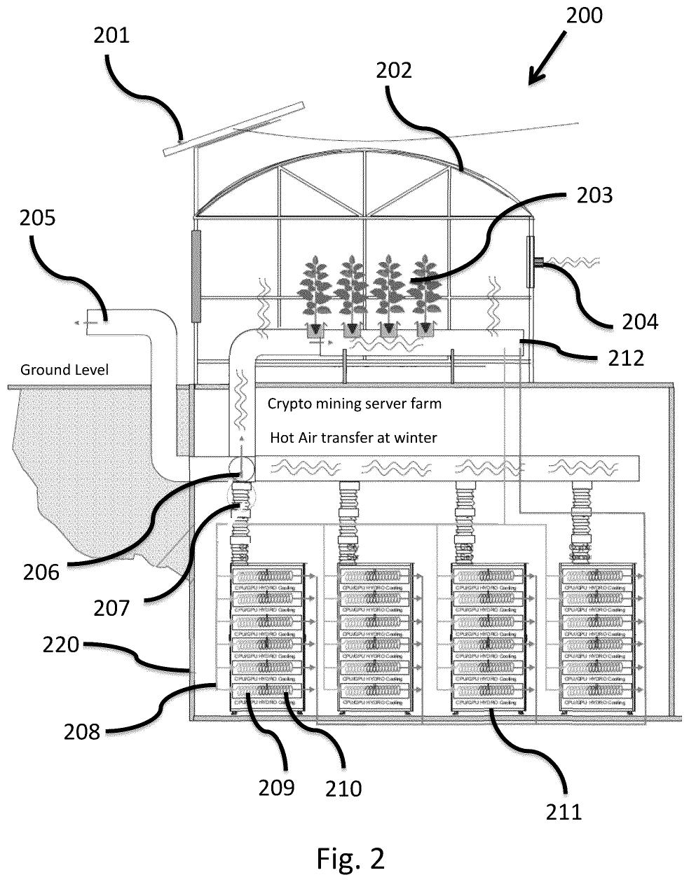

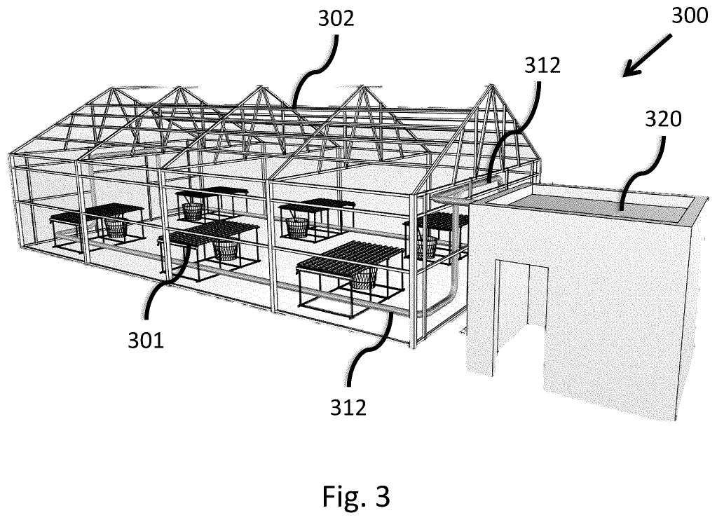

According to an embodiment of the invention, the crypto-mining system 16 of computers and other hardware devices is placed underground (e.g., servers and other components of crypto-mining system 16 are placed in a heating and cooling room 220 that is located beneath the ground level), optionally, beneath the greenhouse 15 itself (as shown with respect to FIG. 2). According to another embodiment of the invention, the crypto-mining system 16 of computers and other hardware devices is placed in a heating and cooling room 320 that is located above the ground level, optionally, adjacent to a greenhouse 302 (as shown with respect to FIG. 3). The crypto-mining temperature regulation system can include any of the following: a plurality of fans, air conditioning units, pipes, liquid coolant flow systems, etc. In one embodiment heat directly generated from the crypto-mining system's hardware heats the air, which is then transferred via vents, to the greenhouse 15. In another embodiment, heat generated from the crypto-mining system's hardware heats water in pipes which is then transferred to the piping system in a greenhouse, heating the interior of the greenhouse. In one embodiment, the internal atmosphere of the greenhouse is heated whereas in another embodiment the soil and/or water of the crop is heated.

In one embodiment any component that requires cooling in the crypto-mining system 16 can be immerse in liquid coolant and/or be in thermal contact with said components using a liquid cooling piping system. According to some embodiments of the invention, the cooling the crypto-mining system 16 may utilize CO₂ based cooling arrangement in any suitable form of form (e.g., gas, liquid or solids).

According to some embodiments of the invention, embodiment, a carbon capture device 10 is also incorporated into the present invention. The stated goal is threefold: 1) to reduce the carbon content in the atmosphere, 2) to utilize CO₂ for fertilization of crops in the greenhouse and 3) to be used as a coolant for the crypto-mining system 16. In an embodiment, the carbon capture device is connected to the power supply 11 and removes carbon dioxide from the outside atmosphere. This CO₂ is then directed towards the interior atmosphere of the greenhouse 15. CO₂ is a key component in photosynthesis; this embodiment helps to improve crop yield and production.

In a further embodiment, CO₂ captured from the carbon capture device 10 is directed to a CO₂ liquefaction system. The said CO₂ is then liquefied, typically below −50° C. The liquefied CO₂ is then directed towards the crypto-mining temperature regulation system 14 so that it can be used to cool the crypto-mining system 16.

### Example 1—Winter Mode

FIG. 2 shows a schematic representation of the present invention in ‘winter mode’. For the purposes of detailing this example′ winter mode′ refers generally to the functioning of this invention during the winter season. However, in colder climates, this mode may be appropriate in a season that is not the winter per se, but one that is generally cold. Winter temperatures can typically be anywhere between −50° C. to 20° C. This figure shows the environment regulation system 200 as a whole comprising the greenhouse 202, solar panel/s 201, plants/crops 203, exhaust ventilation 204 ejecting hot air out of the greenhouse 202, a further exhaust pipe/vent 205 ejecting hot air into the outer atmosphere and connected to an underground crypto-mining system comprising a plurality of server racks 211, piping 208 containing liquid coolant, a plurality of rack exhaust outputs 207, a valve 206 which is configured to direct hot air either into the interior of the greenhouse 202 or out through the exhaust pipe 205 into the atmosphere outside. As shown in the figure, the crypto-mining system can be modular. In this example four crypto-mining server racks 211 are shown, however, this can be scaled up to include any number of servers required. This is also the case for the number of crops, vertical farm units or greenhouses themselves i.e., they can be scaled to include more units. In one embodiment, the liquid coolant flows through the system and can deliver hot or cold liquid directly to the plant soil and/or water via a piping arrangement 212. As stated above, running a crypto-mining server releases a lot of heat energy. Liquid coolant in pipes 208 surrounding the crypto-mining servers 211 are in thermal contact. This said liquid coolant cools the crypto-mining servers 211. When the liquid coolant 209 flows through pipes into the crypto-mining server/s 211 it cools them. The coolant is subsequently heated 210 as it leaves the crypto-mining servers 211. In an embodiment, this heated coolant 210 can be used to warm the soil and/or water that the crops 203 are grown in. The solar panels 201 can be used to continuously cool the liquid coolant, to ensure that the crypto-mining servers remain operating at an optimal temperature. When the interior of the greenhouse is too warm then hot air can be released into the outside atmosphere through a vent 204 on the exterior wall of the greenhouse. When the temperature inside the greenhouse is too cold, the hot air generated by the crypto-mining servers flows through the exhausts 207 and can follow one of two paths: 1) the valve 206 can direct hot air directly into the greenhouse, warming it, or 2) the valve 206 can direct hot air out of the system and into the outside atmosphere by an exhaust pipe/vent 205.

### Example 2—Summer Mode

Many of the principles described in Example 1 apply for the greenhouse functioning during the summer, or hotter, season, but in reverse. Typically, summer temperatures will be between 20 to 55° C. In the summer mode, more energy will be generated by the solar panels 201, which will enable the temperature regulation system within the greenhouse to function as well as the cooling system for the crypto-mining servers. In ‘summer mode’, so as not to overheat the greenhouse, the ventilation system releases the hot air generated by the crypto-mining servers as hot air through ventilation pipes 205, wherein a valve 206 directs the said hot air outside.

FIG. 3 schematically illustrates an environment regulation system 300 installed above the ground level, according to an embodiment of the invention. Environment regulation system 300 may operate similarly to system 200, except that a heating and cooling room 320 is located above the ground level and adjacent to a greenhouse 302. In this embodiment, system 300 delivers hot or cold liquid directly to a plurality of raised beds 301 (each containing the plant soil and/or water) via a duct system 312.

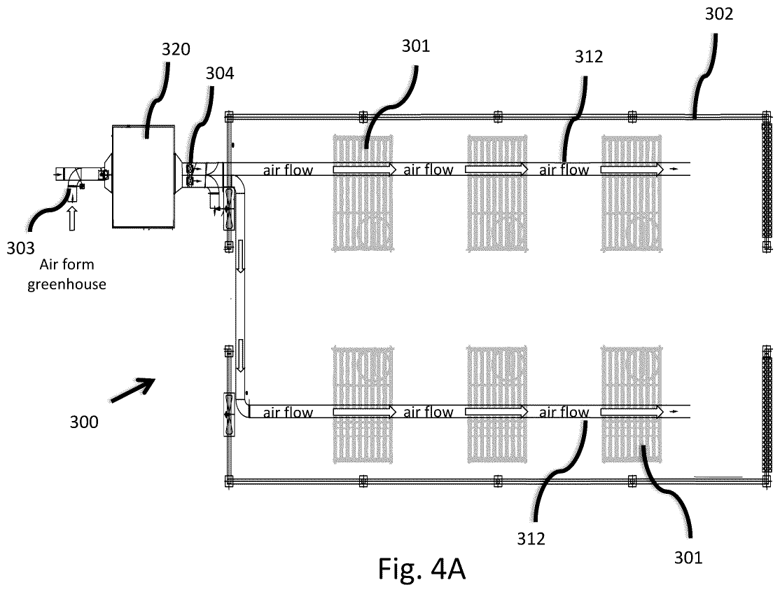

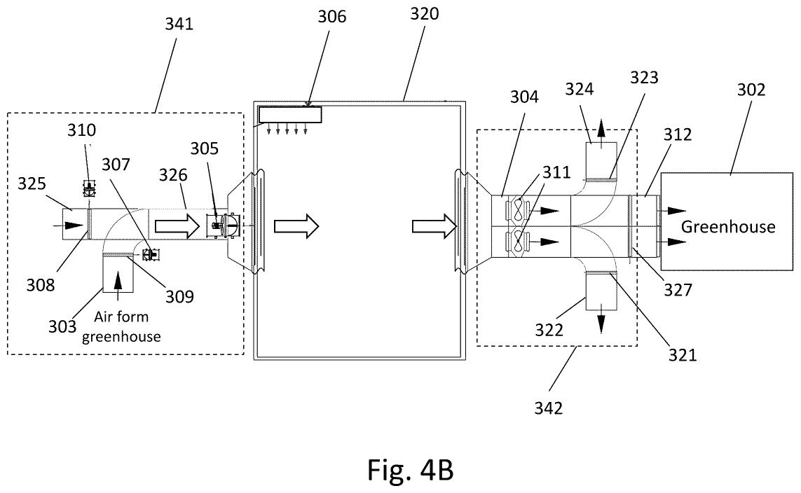

FIG. 4A schematically illustrates a transparent top view of the environment regulation system 300, according to an embodiment of the invention. In this view, it can be seen how duct system 312 delivers hot or cold liquid directly to the plurality of raised beds 301 installed within greenhouse 302. In this embodiment, air from greenhouse 302 enters heating and cooling room 320 via duct 303, and heated/cooled air flows out of room 320 via one or more output ducts 304 into greenhouse 302 through duct system 312.

FIG. 4B schematically illustrates a detailed view of ducts arrangement in conjunction with heating and cooling room 320, according to an embodiment of the invention. In this embodiment, the arrangement of the ducts comprises an input ducts arrangement 341 (e.g., as indicated by the dotted line located at one side of room 320) and an output ducts arrangement 342 (e.g., as indicated by the dotted line located at another side of room 320).

For example, input ducts arrangement 341 may comprise the following components a ventilation blower 305 located within a duct section 326, at the entrance to room 320, to create a blast of air into room 320, and dampers such as dampers 308 and 309 (i.e., each damper is a valve or plate that stops or regulates the flow of air inside a duct). Damper 308 is located at a duct section 325, and it can be controlled by a motor 310 to stop or regulate the flow of ambient air that may be received (e.g., from the outside atmosphere). Damper 309 is located at a duct section 303 and can be controlled by a motor 307 to stop or regulate the airflow from greenhouse 302. In this embodiment, duct sections 308 and 303 are connected in flow communication with duct section 326, through which air flows into room 320. At the output side of room 302, output ducts arrangement 342 comprises one or more fans 311 located at duct section 304, to facilitate the flow of air out of room 320 and into duct system 312 at greenhouse 302. One or more dampers 327 can be used (e.g., at the entrance to duct system 312) to stop or regulate airflow into greenhouse 302. According to some embodiment of the invention, output duct arrangement may comprise one or more exhaust pipes, such as 322 and 324, to direct air out of the system and into the outside atmosphere. One or more exhaust pipes, such as 322 and 324, can be controlled by suitable dampers 321 and 323, respectively. According to some embodiments of the invention, heating and cooling room 320 may be equipped with an air conditioning system 306 adapted to further regulated system 300.

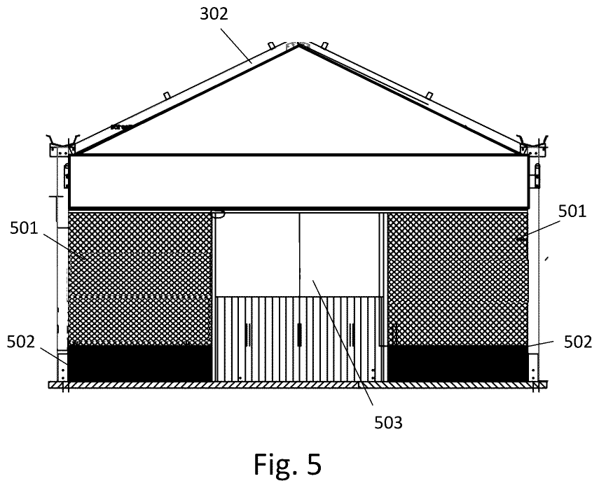

FIG. 5 schematically illustrates the greenhouse 302 provided with a pad climate system, according to an embodiment of the invention. The pad climate system comprises pads 501 (e.g., made of cellulose or plastic) for enhancing the cooling of greenhouse 302. The pads are installed on one or more greenhouse 302 walls and are configured to be watered by a pump 502. The pad climate system can be used as a complementary solution for efficient evaporative cooling of greenhouse 302 to facilitate the temperature regulation within greenhouse 302 and the cooling system for the crypto-mining servers. In this embodiment, the pads are installed adjacent to entrance door 503 of greenhouse 302.

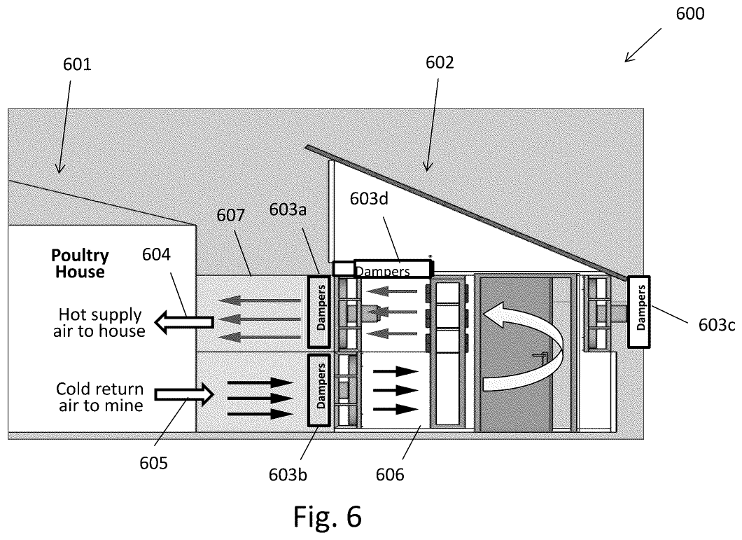

In another embodiment, the hybrid system is adapted for use in poultry houses, specifically for broilers and egg production. FIG. 6 schematically illustrates a livestock environment regulation system 600, according to an embodiment of the invention. System 600 comprises a poultry house 601 and an energy-intensive facility 602 (i.e., a heater such as a crypto miner).

According to an embodiment of the invention, system 600 integrates dampers (e.g., as indicated by numerals 603a-603d) strategically placed within the ventilation ducts (e.g., such as duct 607 through which hot supply air 604 form energy-intensive facility 602 enters poultry house 601, and duct 606 through which cold air 605 from poultry house 601 returned to energy-intensive facility 602) to optimize air circulation and thermal regulation. These dampers allow for precise control over airflow, ensuring that the temperature and humidity within the housing (i.e., poultry house 601 and energy-intensive facility 602) are maintained at optimal levels for the specific needs of various livestock, such as poultry, pigs, and dairy cows, as well as for the crypto-miner system operated within energy-intensive facility 602). By adjusting the damper settings, system 600 can respond dynamically to changes in environmental conditions or the specific requirements of different growth stages, thereby improving animal comfort, reducing stress, and enhancing overall health and productivity. Furthermore, the use of dampers contributes to the energy efficiency of the system, as it prevents unnecessary energy loss by controlling the volume of conditioned air distributed throughout the housing.

Maintaining an optimal temperature in these controlled coops may provide several advantages for various types of livestock, including poultry, pigs, and dairy cows. The benefits may include:
Improved growth and health—the system enables livestock to maintain their ideal body temperature, promoting faster growth and healthier animals, leading to higher yields and more profitable operations.
Reduced stress-consistent temperature control reduces stress levels in animals, improving welfare and lowering the risk of disease.
Better feed conversion-livestock kept at a consistent temperature are more efficient at converting feed into body mass, helping to reduce feed costs and enhance profitability.
Enhanced reproductive performance-temperature control also aids in improving reproductive performance, leading to higher conception rates and more reliable breeding outcomes.
Reduced mortality—by mitigating the risks associated with extreme temperatures, particularly for young or weak animals, the system helps reduce mortality rates, thereby protecting the overall profitability of the operation.

The hybrid system 600 for heating and cooling chicken coops operates as a closed system utilizing heat energy dissipated from energy-intensive facilities 602 such as data centers, AI systems, and crypto-mining operations. It autonomously controls the structure of the chicken coop, adjusting the temperature in accordance with the growth stages of the poultry. This ensures an optimal environment for the animals, enhancing productivity and welfare while minimizing energy usage.

According to an embodiment of the invention, the autonomous control system in the environment regulation system employs sensors and predictive algorithms to manage the temperature in the controlled environment area. This system continuously monitors environmental parameters such as temperature, humidity, and growth stage of the plants or livestock.

In this embodiment, the autonomous control system comprises:
Sensors: deployed throughout the controlled environment area, sensors collect real-time data on temperature, humidity, and other relevant conditions. This data is transmitted to a central processing unit for analysis.
Predictive Algorithms: The central processing unit uses algorithms to forecast future environmental conditions based on historical data, seasonal patterns, and current sensor readings. These forecasts help anticipate changes and adjust the temperature regulation systems preemptively.
Automated Controls: The control system utilizes the data and predictions to automatically adjust the operation of the temperature regulation systems. For example, if the system predicts a temperature drop due to an upcoming cold front, it will preemptively activate heating elements to maintain optimal conditions in the controlled environment area.
Integration with Energy Systems: The control system integrates with the power source and energy-intensive system to optimize energy use. By coordinating the activation of the temperature regulation systems with the heat dissipated from the energy-intensive system, the control system ensures that energy is used efficiently, minimizing waste and reducing operational costs.

This detailed approach allows for precise and adaptive regulation of the controlled environment, enhancing productivity and sustainability while accommodating varying conditions and needs.

Overall, this hybrid system provides a versatile solution for both agricultural and livestock applications, leveraging renewable energy and advanced control systems to maintain ideal conditions for growth, health, and productivity in a sustainable manner.

All the above description and examples have been given for the purpose of illustration and are not intended to limit the invention in any way. Many different mechanisms, methods of cooling, temperature regulation elements can be employed, all without exceeding the scope of the invention.

1. An environment regulation system comprising:
a controlled environment area, including at least one of a greenhouse or a livestock housing unit;
a first temperature regulation system for said controlled environment area;
an energy-intensive system comprising a plurality of computers and/or servers, wherein heat energy dissipated from the energy-intensive system is used to regulate the temperature in the controlled environment area, wherein the energy-intensive system further comprises a second temperature regulation system configured to maintain the operational temperature of the computers and/or servers within an optimal temperature range;
a power source configured to activate the first temperature regulation system in the controlled environment area and the second temperature regulation system for the energy-intensive system; and
a control system configured to adjust the operation of the first temperature regulation system based on environmental parameters including but not limited to growth stages, seasonal variations, and other relevant factors.

2. The environment regulation system of claim 1, wherein the controlled environment area is adapted for agricultural applications, including greenhouses for growing plants and poultry coops for broiler and egg production.

3. The environment regulation system of claim 1, wherein the control system includes sensors and automated controls that dynamically adjust the temperature regulation based on real-time data of environmental conditions and growth stages of the plants or livestock.

4. The environment regulation system of claim 1, wherein the control system includes a predictive algorithm that considers seasonal changes and other environmental parameters to optimize temperature regulation throughout the year.

5. The environment regulation system of claim 1, wherein the physical structure of the controlled environment area includes design features to enhance thermal insulation and energy efficiency.

6. The environment regulation system of claim 1, wherein the design features to enhance thermal insulation and energy efficiency are selected from the group consisting of: thermal screens, cooling system, ventilation, irrigation system, duct system, carbon capture device, or any combination thereof.

7. The environment regulation system of claim 1, wherein the power source comprises a renewable energy source, a grid power source, or a combination thereof.

8. A method of regulating the environment in a controlled area comprising:
dissipating heat energy from an energy-intensive system to the controlled environment area;
adjusting the temperature in the controlled environment area using a first temperature regulation system based on real-time data and predictive algorithms that account for growth stages, seasonal variations, and other environmental parameters;
maintaining optimal operational temperature of the energy-intensive system using a second temperature regulation system; and
utilizing a control system to coordinate the operation of the temperature regulation systems and the power source to ensure efficient energy use.
